(19) United States
(12) Patent Application Publication
(10) Pub. No.: US 2019/0189885 A1
(43) Pub. Date: Jun. 20, 2019

(54) THERMOELECTRIC GENERATOR

(71) Applicant: THERM-TECH AS, Narvik (NO)

(72) Inventor: Bjørn Eirik Birkeland, Narvik (NO)

(21) Appl. No.: 15/893,347

(22) Filed: Feb. 9, 2018

Related U.S. Application Data
(60) Provisional application No. 62/599,584, filed on Dec. 15, 2017.

(51) Int. Cl. H01L 35/30; H01L 35/02

(52) U.S. Cl. CPC H01L 35/30; H01L 35/02

(57) ABSTRACT

Aspects of the invention described herein relate to thermoelectric generator devices and uses thereof. Preferred aspects include thermoelectric generator devices that have a base including an air inlet, a housing having a first end connected to the base and a second end opposite the first end, a cap connected to the second end of the housing and including an air outlet, a heat source connected to the base, a thermoelectric module positioned between the heat source and the second end of the housing, wherein the thermoelectric module includes a hot side heat sink; and a cold side heat sink; and a heat shield assembly including an outlet wall extending between the hot side heat sink and the second end of the housing, wherein the outlet wall having an outlet aperture configured to permit passage of air from the hot side heat sink to the second end of the housing; and an inlet wall positioned between the hot side heat sink and the first end of the housing, the inlet wall connected to one or both of the outlet wall and the hot side heat sink, the inlet wall configured to direct hot air from the heat source to the hot side heat sink and to direct hot air away from the cold side heat sink.

### CROSS-REFERENCE TO RELATED APPLICATIONS

This application claims the benefit of U.S. Provisional Patent Application No. 62/599,584, filed Dec. 15, 2017, (entitled “THERMOELECTRIC GENERATOR”), the entire disclosure of which is hereby expressly incorporated by reference in its entirety. Any and all priority claims identified in the Application Data Sheet, or any correction thereto, are hereby incorporated by reference under 37 CFR 1.57.

### TECHNICAL FIELD

This application relates to thermoelectric generator devices and uses thereof.

### DISCUSSION OF THE RELATED ART

Thermoelectric generators (TEGs) are used in the power generation, automotive, and other industries to convert heat into electrical energy. Often TEGs are inefficient and fail to efficiently convert heat energy into usable electrical energy. Additionally, due to the use of heat to generate electricity, TEG devices can be dangerous to use indoors and can be difficult to use without heat resistant gloves or other safety equipment.

### SUMMARY

According to some embodiments, a thermoelectric generator device can include a base. The base can have an air inlet. The thermoelectric generator device can include a housing having a first end connected to the base and a second end opposite the first end. The device can include a cap connected to the second end of the housing and including an air outlet. In some embodiments, the device includes a heat source connected to the base. A thermoelectric module positioned between the heat source and the second end of the housing, the thermoelectric module comprising a hot side heat sink and a cold side heat sink. The device can include a heat shield assembly comprising an outlet wall extending between the hot side heat sink and the second end of the housing. The outlet wall can have an outlet aperture, which permits passage of air from the hot side heat sink to the second end of the housing. In some embodiments, the device includes an inlet wall positioned between the hot side heat sink and the first end of the housing, the inlet wall connected to one or both of the outlet wall and the hot side heat sink, the inlet wall, which directs hot air from the heat source to the hot side heat sink and directs hot air away from the cold side heat sink.

In some embodiments, the cold side heat sink extends at least one half of a distance between the first and second ends of the housing.

In some embodiments, the device comprises two cold side heat sinks and two thermoelectric modules, wherein the hot side heat sink is positioned between the two cold side heat sinks and two thermoelectric modules.

In some embodiments, the two cold side heat sinks each comprise an inner surface facing away from the housing and an outer surface facing toward the surface, wherein the inner surfaces of the two cold side heat sinks forms an inner air passage and the space between the housing and the outer surfaces of the two heat sinks forms an outer air passage.

In some embodiments, passage of hot air through the outlet aperture of the outlet wall of the heat shield passes through the inner air passage to the air outlet of the cap, and wherein passage of hot air to the air outlet draws air from the outer air passage to the air outlet.

In some embodiments, the two cold side heat sinks are held to each other via one or more resilient clips, wherein the hot side heat sink is held in place with respect to the two cold heat sinks via compression of the two thermoelectric modules and the hot side heat sink between the two cold side heat sinks.

In some embodiments, the resilient clips deform in response to expansion and contraction of one or more of the thermoelectric modules, the hot side heat sink, and the cold side heat sinks.

In some embodiments, the hot side heat sink and cold side heat sink are fixed with respect to each other without use of fasteners.

In some embodiments, the base comprises two or more feet, which contact a surface when the thermoelectric generator is set upon the surface, wherein one or more open spaces are created between the two or more feet and the surface when the thermoelectric generator is set upon the surface, and wherein the one or more open spaces facilitate fluid communication between the air inlet and an ambient environment surrounding the thermoelectric generator device.

In some embodiments, the inlet wall of the heat shield has a frustoconical shape having an inlet end with an inlet width and an outlet end with an outlet width, wherein the outlet width is narrower than the inlet width.

In some embodiments, the device further comprises a light source connected to the cap, wherein the thermoelectric module powers the light source.

According to some embodiments, a thermoelectric generator device includes a housing having an inlet wall with an inlet opening, an outlet wall with an outlet opening, an annular wall connected to the inlet and outlet walls and extending therebetween, a housing interior defined by the inlet wall, outlet wall, and the annular wall, and a housing axis extending through a center of the housing interior, through the inlet wall, and through the outlet wall. In some embodiments, the device includes a heat source releasably connected to the inlet wall. The device can include a thermoelectric module positioned within the housing interior between the heat source and the second end of the housing. In some embodiments, the thermoelectric module includes a hot side heat sink having a first end portion, a second end portion, and a connection portion extending therebetween. The thermoelectric module can include a first cold side heat sink positioned on a first side of the hot side heat sink and a second cold side heat sink positioned on a second side of the hot side heat sink. In some embodiments, the thermoelectric module includes a heat shield having a guide wall positioned between the hot side heat sink and the inlet wall of the housing, the guide wall directing hot air from the heat source to the hot side heat sink and directing hot air away from the first and second cold side heat sinks. In some embodiments, the first end portion of the hot side heat sink has a first cross-sectional area as measured on a first plane parallel to the housing axis, the second end portion of the hot side heat sink has a second cross-sectional area as measured on a second plane parallel to the first plane, and the connection portion has a third cross-sectional area as measured on a third plane parallel to the first plane. In some embodiments, the first plane passes through the first end portion and does not pass through the connection portion or the second end portion, the second plane passes through the second end portion and does not pass through the connection portion or the first end portion; and the third plane passes through the connection portion and does not pass through the first or second end portions. The third cross-sectional area can be less then each of the first and second cross-sectional areas.

In some embodiments, the heat shield comprises walls that surround the connection portion of the hot side heat sink on at least three sides, wherein the walls of the heat shield include an outlet aperture, which permits escape of hot air from within the walls of the heat sink to outlet opening of the outlet wall.

In some embodiments, the connection portion of the hot side heat sink has a cylindrical shape and wherein the third cross-sectional area is a circular cross-section of the connection portion.

In some embodiments, the guide wall of the heat shield is connected to one or both of the first and second end portions of the hot side heat sink.

In some embodiments, fasteners are used to connect the guide wall to the first and second end portions of the hot side heat sink.

In some embodiments, the heat source is connected to the inlet wall of the housing via one or more of a threaded connection, a bayonet connection, and a detent connection.

In some embodiments, the heat source is one or more of a candle, an oil holder, or a gas holder.

In some embodiments, the device further comprises two or more legs connected to the housing, wherein the legs are rotatable with respect to the housing between a first orientation and a second orientation, and wherein the legs space the inlet wall of the housing from a surface upon, which the thermoelectric generator device is set when the legs are in the first orientation and space the inlet wall of the housing a further distance from the surface when the legs are in the second orientation.

In some embodiments, the device further comprises a hanger connected to the housing and, which is configured to attach the thermoelectric generator device to a hook or other affixed structure.

In some embodiments, the device further comprises an electric port, which facilitates electric connection between the thermoelectric generator device and an external device, wherein the external device is one or more of a camera, a phone, a GPS device, a laptop, a tablet, a video game console, or a television, and, wherein the thermoelectric module powers the electric port.

According to some embodiments, a method of providing electrical power to an electrical load includes connecting a heat source to an inlet wall of a housing. The method can include directing heated air from the heat source to a hot side heat sink of a thermoelectric module. In some embodiments, the method includes blocking at least a portion of the heated air from the heat source from a cold side heat sink of a thermoelectric module. The method can include circulating the heated air within a heat shield surrounding at least three sides of a portion of the hot side heat sink. In some embodiments, the method includes directing heated air through an outlet aperture in the heat shield toward an outlet wall of the housing. The method can include pulling cold air through the inlet wall of the housing via a pressure deficit adjacent the inlet wall created by passage of the heated air through the outlet aperture. In some embodiments, the method includes cooling a cold side heat sink of the thermoelectric module using the cold air pulled through the inlet wall. The method can include generating electricity via the thermoelectric module.

In some embodiments, the method includes powering a light using the generated electricity.

In some embodiments, the method includes powering a USB port or other electrical port using the generated electricity.

### BRIEF DESCRIPTION OF THE DRAWINGS

Aspects of the present invention are described with reference to the accompanying drawings, in which like reference characters reference like elements, and wherein.

FIG. 1 is a schematic representation of a TEG device.

FIG. 1A is a chart comparing output power to deltaT.

FIG. 1B is a chart comparing matched load output power to hot side temperature.

FIG. 1C is a chart comparing conversion rate to hot side temperature.

FIG. 2 is a top right perspective view of a first embodiment of a TEG device.

FIG. 3 is a front plan view of the TEG device of FIG. 2.

FIG. 4 is a right side plan view of the TEG device of FIG. 2.

FIG. 5 is a left side plan view of the TEG device of FIG. 2.

FIG. 6 is a back side plan view of the TEG device of FIG. 2.

FIG. 7 is a bottom plan view of the TEG device of FIG. 2.

FIG. 8 is a top plan view of the TEG device of FIG. 2.

FIG. 9 is a top perspective view of a TEG subassembly of the TEG device of FIG. 2.

FIG. 10 is a bottom perspective view of the TEG subassembly of FIG. 9.

FIG. 10A is a partially exploded view of the TEG subassembly of FIG. 9.

FIG. 11 is an exploded view of the TEG subassembly of FIG. 9 with the cold side heat sinks removed.

FIG. 12 is a top perspective view of the TEG subassembly of FIG. 9 with the cold side heat sinks removed.

FIG. 13 is a bottom perspective view of the TEG subassembly of FIG. 9 with the cold side heat sinks removed.

FIG. 14 is a close up cross-sectional view of the heat shield and hot side heat sink of the TEG subassembly of FIG. 9.

FIG. 15 is a cross-sectional view of the TEG device of FIG. 2.

FIG. 16 is a top plan view of the TEG subassembly of FIG. 9.

FIG. 17 is a top right perspective view of a second embodiment of a TEG device with legs in a first configuration.

FIG. 18 is a top right perspective view of the TEG device of FIG. 17 with the legs in a second configuration.

### DETAILED DESCRIPTION

Generally described, the present disclosure relates to thermoelectric generator (TEG) devices configured to convert heat into electricity suitable for powering lights, mobile electronics and/or other electrical devices. The disclosed TEG devices are preferably lightweight and portable. Applications for using the devices include camping or other outdoor activities where access to electric power is otherwise limited. The disclosed TEG devices are also particularly useful in emergency situations, such as when power outages occur or access to shelter is limited.

The unique designs of the disclosed TEG devices preferably limit the amount of heat transferred to outer surfaces of the devices. As such, the disclosed devices can be moved, set on surfaces, and otherwise used with reduced risk of burning a user's hands or damaging the surfaces on which or near which the devices are set or installed. As will be described in more detail below, the unique heat shield designs and heat sink designs of the disclosed TEG devices permit more efficient conversion of heat into electricity than has been previously realized.

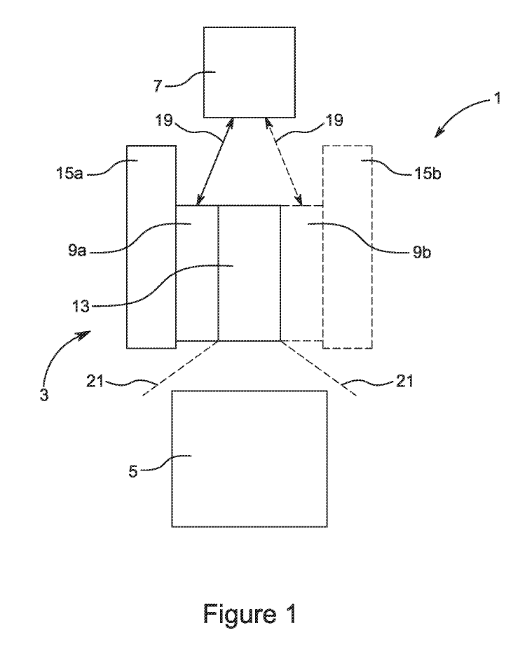

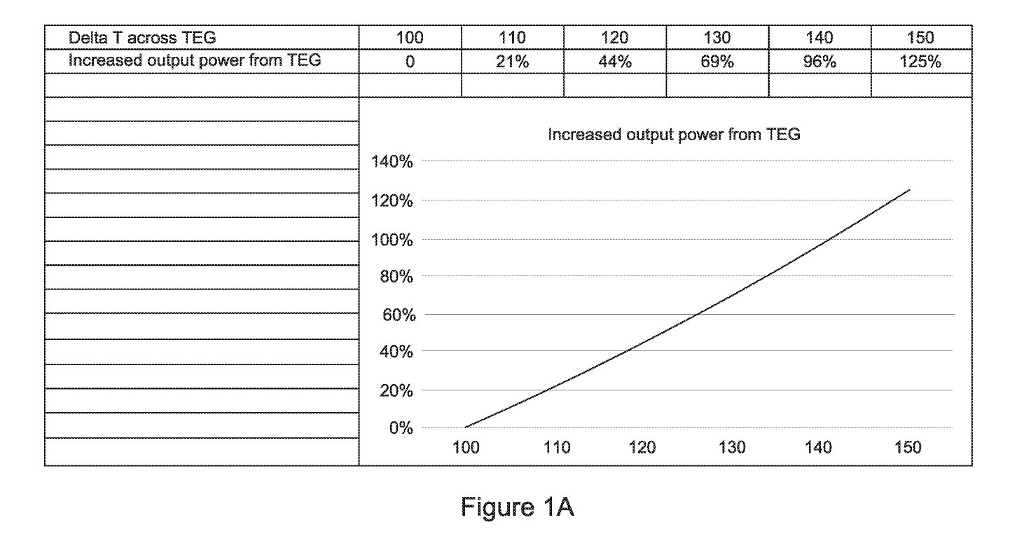

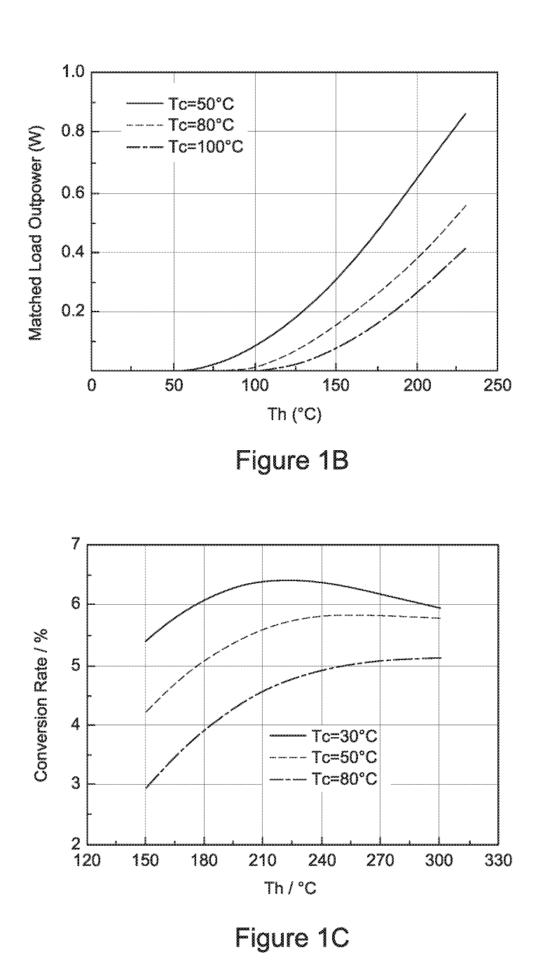

FIG. 1 illustrates a schematic embodiment of a TEG device 1. As illustrated, the TEG device can include a TEG subassembly 3 and a heat source 5. The heat source 5 can be, for example, a candle, a camp heater, a Sterno® tin, a propane burner, a butane burner, or other heat source operational with or without a wick. The TEG device 1 can include a power load 7. The power load 7 can be a light (e.g., an LED or other light source) and/or a port (e.g., a USB, an electrical socket, a mini-USB, and/or other socket or interface configured to transfer electrical power). In some embodiments, the power load 7 can be a speaker and/or a radio. The power load 7 can be configured to operate off of the electrical power generated by the TEG subassembly. The power load 7 can include a battery or other power storage structure configured to store power generated by the TEG subassembly 3 for use at a later time. Power can be transferred from the TEG subassembly 3 to the power load 7 via wired and/or wireless electrical connections 19.

The TEG subassembly 3 can be positioned above the heat source 5. In some embodiments, a hot side heat sink 13 of the TEG subassembly 3 is positioned directly above the heat source 5. As illustrated, the TEG subassembly 3 can include a first TEG module 9a positioned between the hot side heat sink 13 and a first cold side heat sink 15a. The TEG module 9a can be configured to convert heat provided by the hot side heat sink 13 to electricity that is then transferred to the power load 7. More specifically, the TEG module 9a is configured to convert heat flux or deltaT (e.g., the temperature difference between the hot side heat sink 13 and the cold side heat sink 15a) into electrical energy.

As illustrated in FIG. 1A, the greater the deltaT across the TEG, the greater the power output from the TEG. For example, when compared to a deltaT of 100° C., an increase in deltaT to 142° C. produces an improvement of 100% power output. This is due at least in part to the fact that power output is related to (deltaT)². As such, increases in power are realized exponentially as deltaT is increased. It is desirable, therefore, to maximize the difference in temperature between the hot side heat sink and the cold side heat sink.

As illustrated in FIG. 1B, the matched load output power also increases exponentially as the deltaT is increased (e.g., as you increase the hot side temperature “Th” for a given cold side temperature “Tc”).

The overall efficiency of the TEG subassembly 3 can be increased by increasing the deltaT. This is shown in FIG. 1C, which compares the conversion rate (the matched load output power divided by the heat flow through the subassembly 3) to the deltaT. In some instances, as illustrated, a given TEG subassembly 3 may reach a maximum conversion rate at a given particular deltaT. For example, for a cold side temperature of 30° C., some TEG subassemblies may reach a maximum conversion rate at a deltaT of around 200° C. Overall, however, the relationship between conversion rate and deltaT is direct—as deltaT increases, so does conversion rate increase.

The above-described temperature and energy relationships provide some of the explanation for the importance of increasing deltaT in a TEG in order to increase power output. In order to maximize deltaT, it is helpful to minimize heat loss on the hot side heat sink while maximizing heat loss in the cold side heat sink. Minimizing heat loss can include reducing conductive, convective, and/or radiation heat loss. Radiation heat loss is generated proportionally to temperature multiplied by the surface area of the heat sink. As such, one way to reduce heat loss due to radiation and convection is to minimize the surface area of the hot side heat sink.

Preferably, the TEG subassembly 3 includes a second TEG module 9b. The second TEG module 9b can be positioned on a side of the hot side heat sink 13 opposite the first TEG module 9a. In some embodiments, the second TEG module 9b is positioned on a side of the assembly 3 other than the side opposite the first TEG module 9a. A second cold side heat sink 15b can be positioned on a side of the second TEG module 9b opposite the hot side heat sink 13. In some such embodiments, the cold side heat sinks 15a, 15b can apply pressure to the TEG modules 9a, 9b to keep the TEG subassembly 3 in an assembled configuration. In some embodiments, this pressure is applied by resilient and/or flexible clips or other attachments that are configured to flex in response to expansion or contraction of one or more components of the TEG subassembly 3. Preferably, the heat sinks and TEG modules are held together without use of bolts, screws, or other fasteners. Avoiding use of fasteners to hold these components to each other reduces the risk of over-compression of the components when, for example, one or components expand as their respective temperatures increase.

As illustrated in FIG. 1, the TEG device 1 can include a heat shield 21. The heat shield 21 can be configured to reduce passage of hot air from the heat source 5 to the cold side heat sink(s) and to direct hot air to the hot side heat sink 13. Such directing of hot air from the heat source 5 increases the temperature differential between the hot side heat sink 13 and the cold side heat sink(s) 15a, 15b, thereby increasing the amount of electricity produced by the TEG module(s) 9a, 9b. As explained in more detail below, the heat shield 21 can include an inlet portion. The inlet portion of the heat shield 21 can be positioned at least partially between the heat source 5 and the TEG subassembly 3. In some embodiments, heat shield 21 includes one or more walls surrounding the hot side heat sink 13. For example, the heat shield 21 can surround all or a portion of the hot side heat sink 13 on at least three sides (e.g., two or more lateral sides and a top side). The heat shield 21 can be configured to retain hot air in the vicinity of the hot side heat sink 13 for a longer period of time than if the heat shield 21 were absent from the TEG device 1.

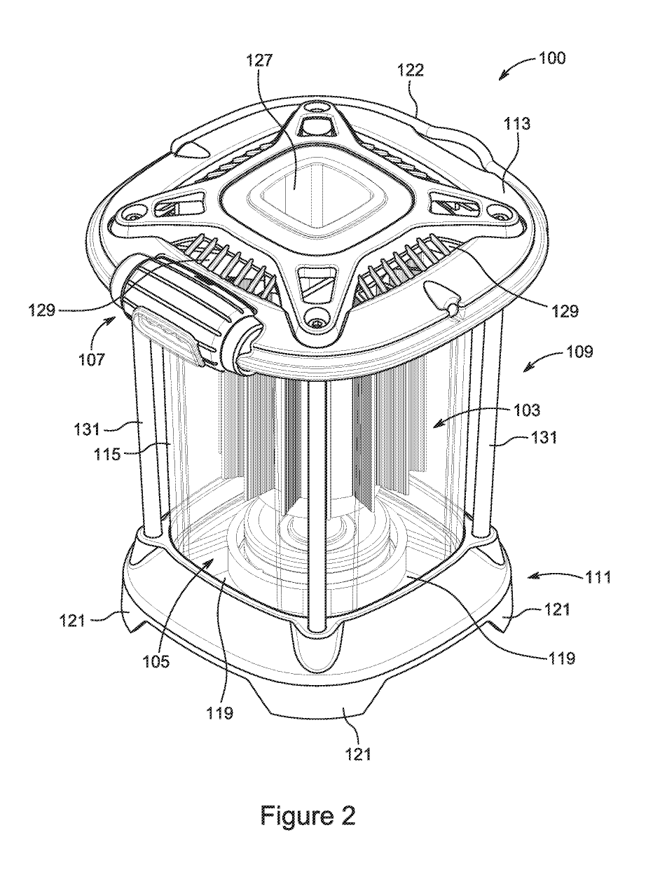

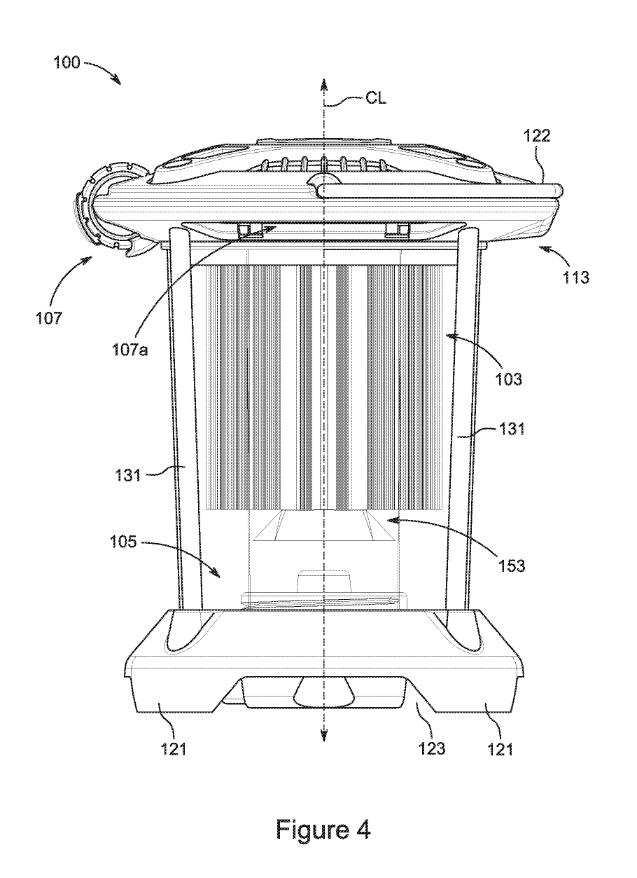

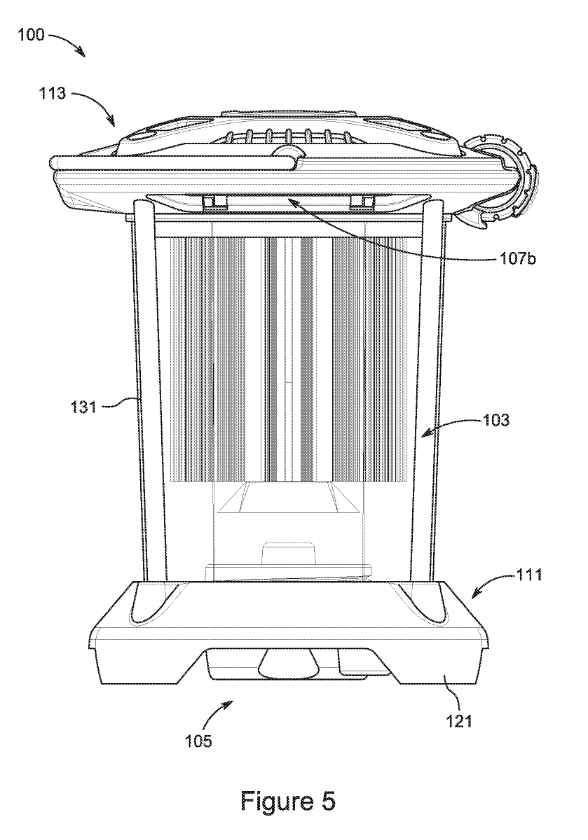

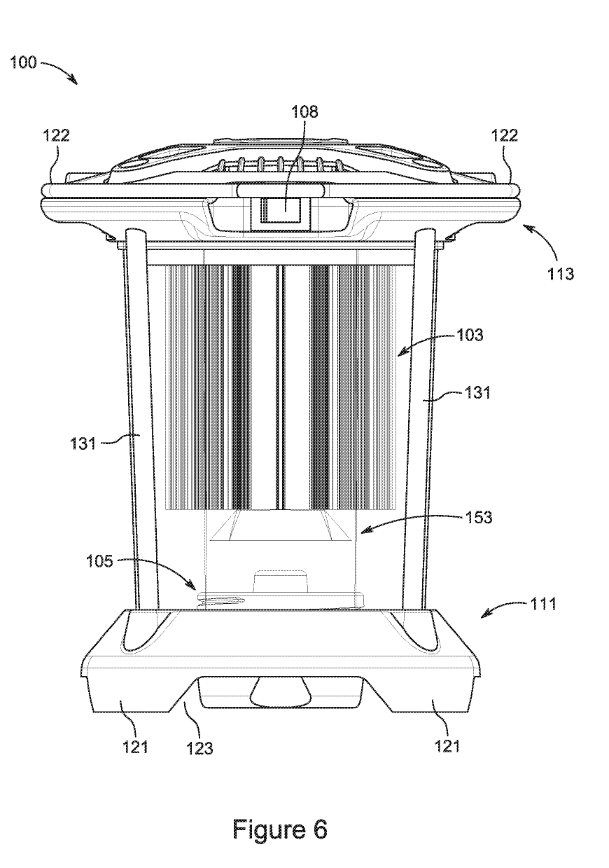

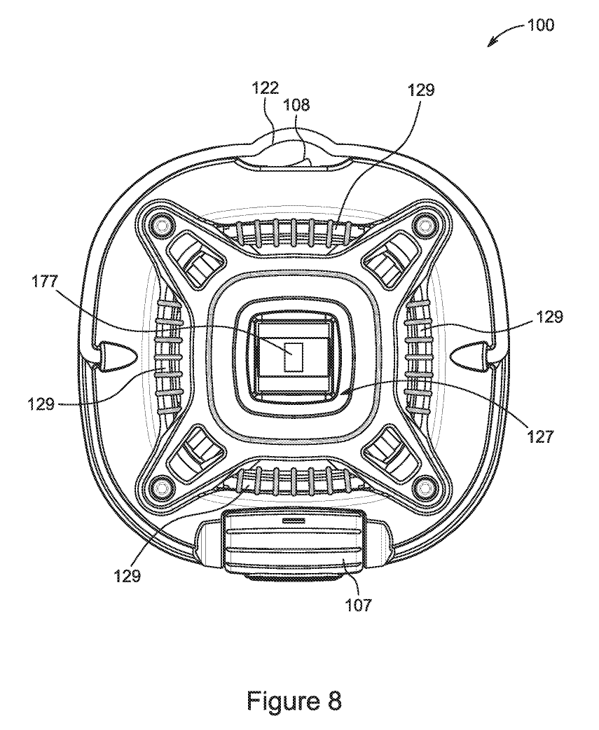

FIGS. 2-8 illustrate an embodiment of a TEG device 100. The TEG device 100 can include many or all of the features described above with respect to the TEG device 1. For example, as illustrated in FIG. 2, the TEG device 100 can include a TEG subassembly 103. The TEG subassembly 103 can be positioned above a heat source 105. In some embodiments, the TEG device 1 include a light 107 or other power load (e.g., USB port, mini-USB port, electrical socket, and/or some other power load). The light 107 can be hinged to allow for redirection of the light in various directions without movement of the other components of the TEG device 100. The power load can be configured to operate via electric power produced by the TEG subassembly 103. Electric power from the TEG subassembly 103 can be transferred to the power load and/or to a battery via wired or wireless power transfer. In some embodiments (FIG. 6), a switch 108, button, knob, or other actuation structure can be used to transition the power load/light 107 between one or more configurations (e.g., ON/OFF, dimming, voltage/amperage ratings, etc.). In some embodiments, the TEG device 100 can include one or more additional lights 107a (FIG. 4), 107b (FIG. 5). The TEG device 100 can preferably be transitioned between different lighting modes wherein different combinations of the lights 107, 107a, 107b are shut off or powered.

The TEG device 100 can include a housing 109. The housing 109 can include a base 111 and a cap 113. The base 111 can be positioned at a bottom end of the housing 109 and the cap 113 can be positioned at a top end of the housing 109. An annular or partially annular wall 115 can extend between the base 111 and the cap 113. All or a portion of the wall 115 can be constructed from a transparent or translucent material. In some embodiments, the wall 115 includes portions having light-reflective properties. The wall 115, cap 113, and base 111 can define a housing interior. In some embodiments, one or more of the heat source 105 and the TEG subassembly 103 are positioned at least partially within the housing interior. In some embodiments, the TEG device 100 includes one or more columns 131 or other bracing structures connected to the cap 113 and the base 111. The columns 131 increase the structural stability of the TEG device 100.

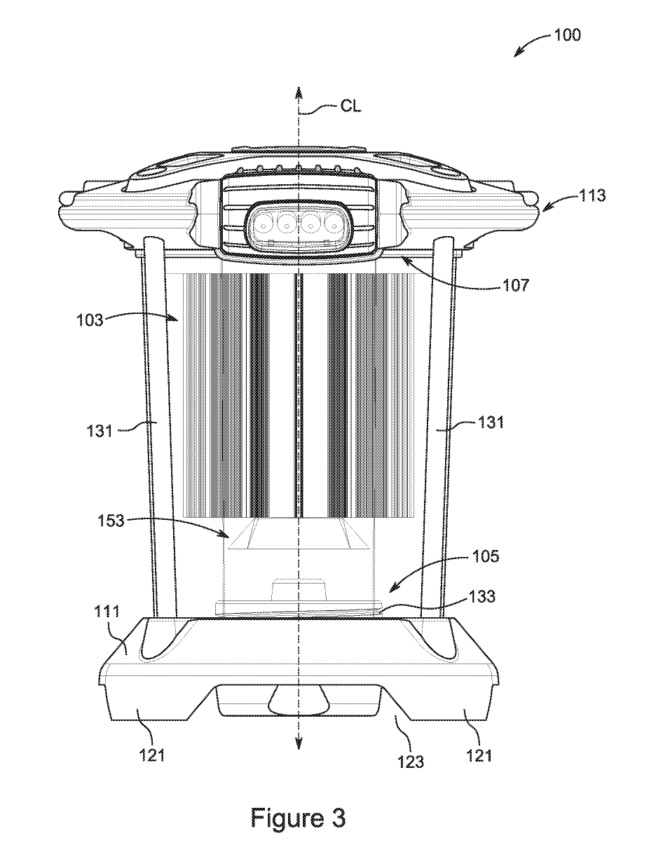

In some embodiments, the base 111 and/or a lower portion of the wall 115 includes one or more air inlets 119. The one or more air inlets 119 can be configured to facilitate passage of air into the housing interior from an ambient environment surrounding the TEG device 100. Passage of air into the housing interior provides oxygen to the heat source 5 and/or cooling to the cold side heat sinks. In some embodiments, the base 111 includes one or more feet 121 configured to contact a surface upon which the TEG 100 is set. As illustrated in FIG. 3, the spaces 123 between the feet 121 can be configured to facilitate access of ambient air to the air inlets 119.

Returning to FIG. 2, the cap 113 or some other portion of the TEG device 100 can include a hanger 122. The hanger 122 can include a generally U-shaped structure connected at one or both ends to the housing 109 (e.g., to the cap 113) of the TEG device 100. The hanger 122 can be configured to facilitate hanging the TEG device 100 from a hook, cantilevered structure, or other mounting point as an alternative to setting the TEG device 100 down upon a surface. The hanger 122 provides a convenient mechanism by which the device 100 may be carried by a user.

The cap 113 and/or an upper portion of the wall 115 can include one or more air outlets. For example, the cap 113 can include a central air outlet 127. The central air outlet 127 can be positioned in and/or around a center of the cap 113. In some embodiments, the central air outlet 127 includes ribs, screens, or other structures extending over the opening. In some embodiments, the cap 113 includes one or more secondary air outlets 129. The secondary air outlets 129 can be spaced around the central air outlet 127.

As illustrated in FIG. 3, the heat source 105 can be positioned at a lower end of the housing 109. In some embodiments, the heat source 105 is connected to the base 111 of the housing 109. The connection between the heat source 105 and the base 111 or other portion of the housing 109 can be releasable. For example, the heat source 105 can include threads 133 configured to engage with threads on the base 111. In some embodiments, the heat source 105 includes bayonet fittings, detent structures, and/or other structures configured to facilitate releasable connection between the heat source 105 and the housing 109 (e.g., the base 111 of the housing 109). In some embodiments, the heat source 105 includes an outer housing that has the connection structure(s) described above and that is configured to receive a candle, Sterno® can, butane burner, propane burner, wood for burning, and/or some other source of fuel for creating heat. Releasability of the heat source 105 (e.g., the housing of the heat source 105) from the housing 109 facilitates convenient refueling or other maintenance/replacement of the heat source 105 or some subcomponent thereof.

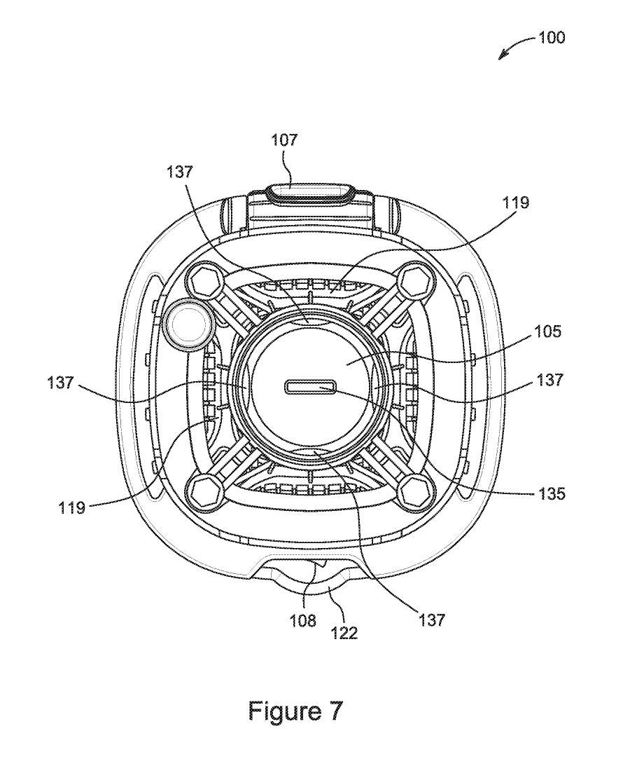

As illustrated in FIG. 7, the heat source 105 or outer housing thereof can include one or more engagement portions configured to facilitate engagement and disengagement of the heat source 105 from the housing 109. For example, the heat source 105 can include a slot 135 for engagement with a screwdriver or other tool. In some embodiments, the heat source 105 includes one or more surface features 137 (e.g., flattened surfaces, gnarled surfaces, roughened surfaces, etc.) configured to facilitate gripping of the heat source 105 or heat source housing by a user's hand or by a tool such as, for example, pliers or a wrench.

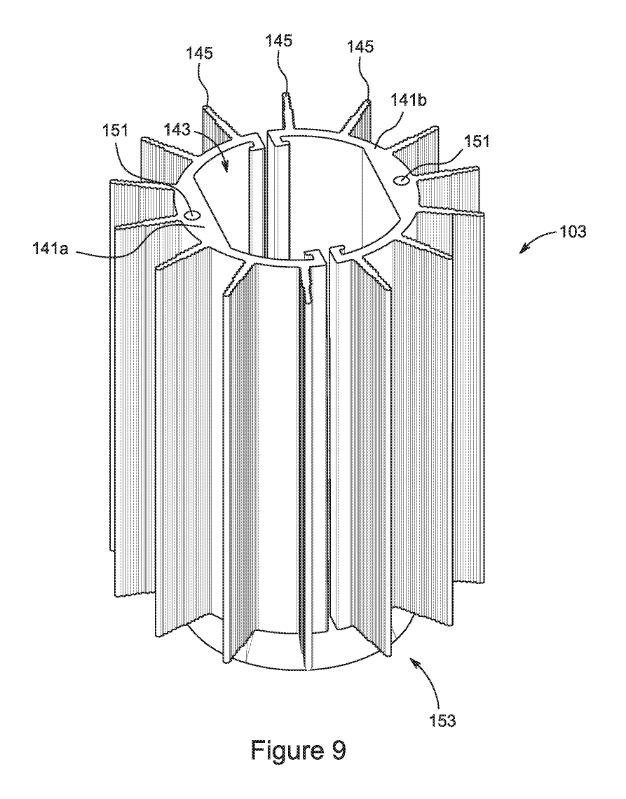

As illustrated in FIG. 9, the TEG subassembly 103 can include one or more cold side heat sinks. For example, the TEG subassembly 103 can include two cold side heat sinks 141a, 141b (collectively “141”). The cold side heat sinks 141 can be assembled to form a generally tubular structure havening an interior passage 143. The cold side heat sinks 141 can include one or more fins 145, ridges, protrusions, and/or structures configured to transfer heat from the cold side heat sink 141 to the housing interior. The fins 145 can be textured with smaller ridges, fins, protrusions, apertures, divots, dimples, or other surface features to further facilitate heat transfer from the cold side heat sink 141.

The cold side heat sinks 141 can include apertures 151 or other attachment structures configured to facilitate attachment of the cold side heat sinks 141 to the housing 109. For example, one or more fasteners can be inserted through a portion of the cap 113 and into the apertures 151 to connect the cold side heat sings 141 to the housing 109.

The TEG subassembly 103 can include a heat shield 153. As illustrated in FIG. 9, the heat shield 153 can be positioned at or near the bottom end of the cold side heat sinks 141. In some embodiments, the heat shield 153 is positioned at least partially within the interior passage 143 of the TEG subassembly 103.

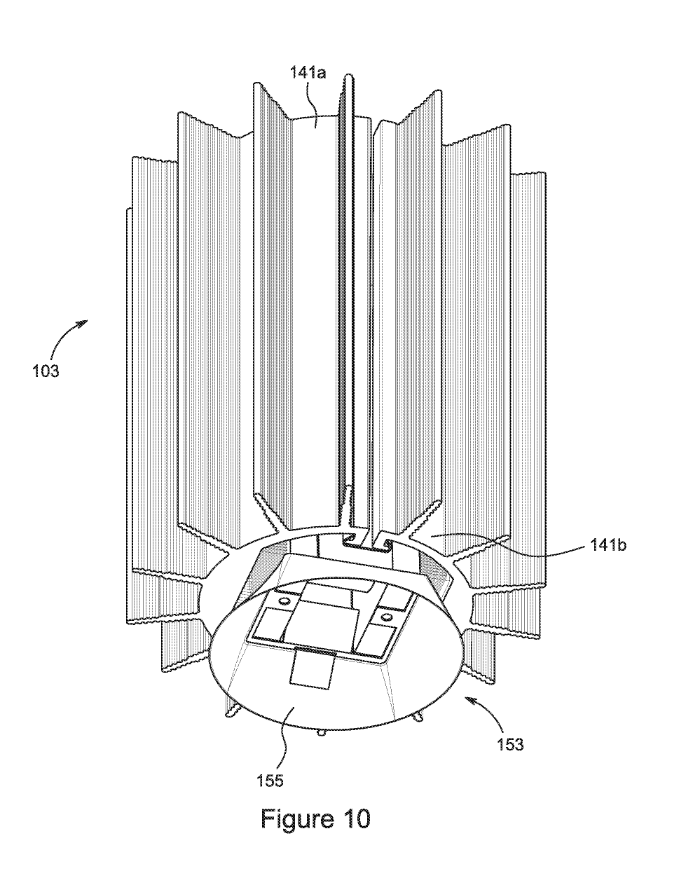

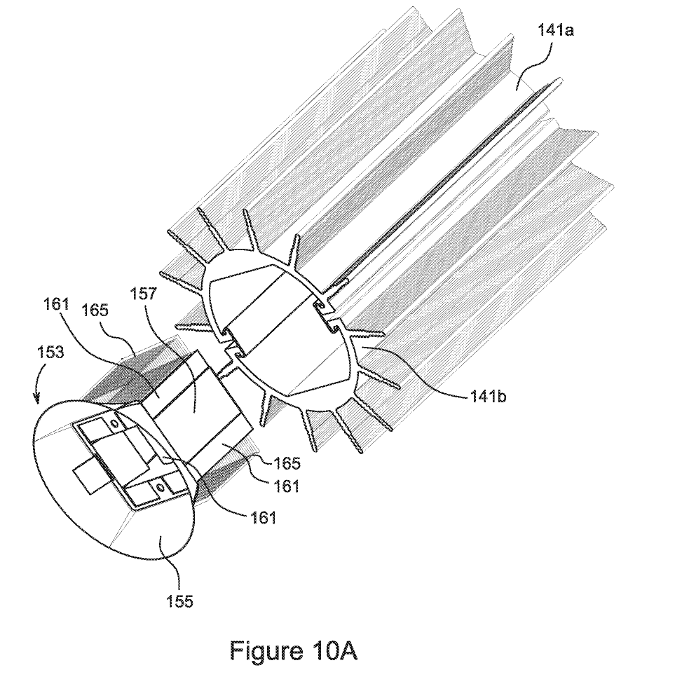

As illustrated in FIG. 10, the heat shield 153 can include an entry portion 155. The entry portion 155 can be, for example, a frustoconical wall, a truncated pyramidal wall, a cylindrical wall, or some other shaped-wall. The entry portion 155 of the heat shield 153 can be tapered such that the lower end of the entry portion 155 of the heat shield can have a cross-sectional area (e.g., as measured perpendicular to a housing axis or centerline CL—see FIGS. 3-4) greater than a cross-sectional area of the upper end of the entry portion 155. Tapering the entry portion 155 of the heat shield 153 accelerates the heated air through the entry portion 155.

As illustrated in FIG. 10A, the heat shield 153 can include an upper portion 157. In some embodiments, the upper portion 157 is formed as a unitary part with the entry portion 155 of the heat shield 153. In the illustrated embodiment, the upper portion 157 of the heat shield 153 is formed as a separate part from the entry portion 155. The upper portion 157 of the heat shield 153 can at least partially surround all or a portion of the hot side heat sink 161 of the TEG subassembly 103.

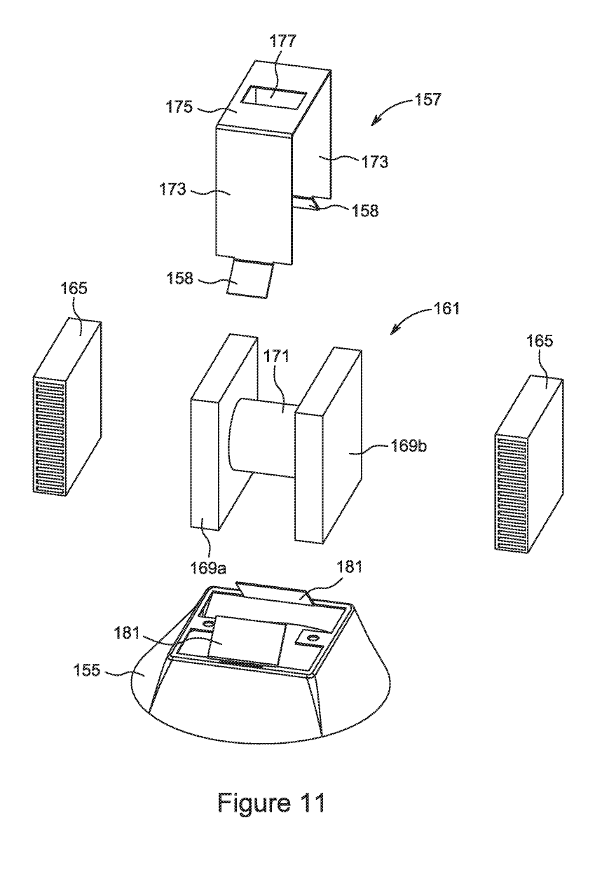

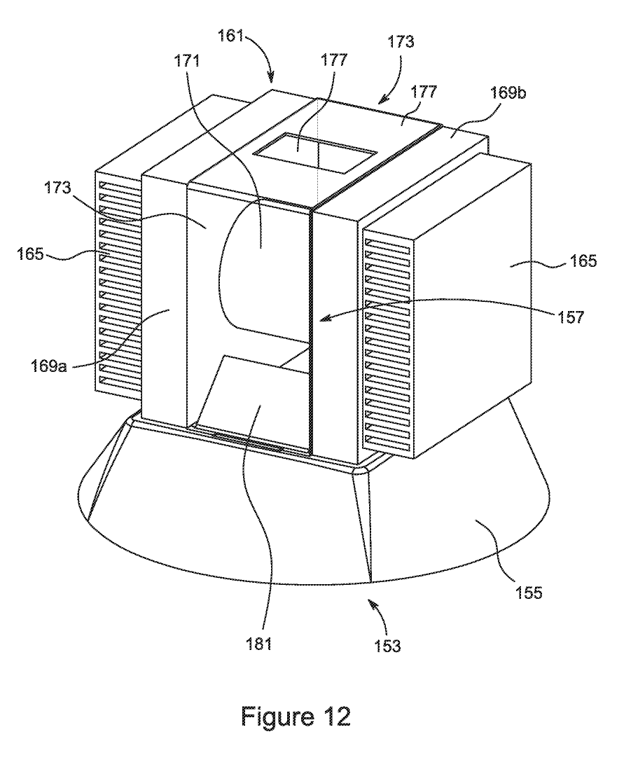

As illustrated in FIGS. 11-12, the upper portion 157 of the heat shield 153 can include one or more attachment structures. For example, the upper portion 157 can include one or more tabs 158 configured to mate with slots in the entry portion 155 of the heat shield 153. The tabs 158 can be resilient and/or flexible to facilitate deformation of the tabs 158 as they are mated with the entry portion 155. The upper portion 157 can include alternative and/or additional attachment structures such as, for example, magnets, protrusions, hooks, clips, threading, bayonet structures, and/or some other structure or combination of structures configured to facilitate mating of the upper portion 157 to the entry portion 155 of the heat shield 153. In some embodiments, the upper portion 157 of the heat shield 153 is attached to the entry portion 155 using adhesives.

The upper portion 157 of the heat shield 153 can include one or more sidewalls 173. The sidewalls 173 can extend vertically. In some embodiments, the sidewalls 173 include curved and/or sloped portions. A top shield wall 175 can extend between the sidewalls 173. In some embodiments, all or a portion of the sidewalls 173 and/or top shield wall 175 are formed as an arcuate and/or continuous wall. The top shield wall 175 can include a hot air outlet. The hot air outlet can be, for example, an aperture 177 in the top shield wall 175. In some embodiments, the aperture 177 extends through one or more of the sidewalls 173. The aperture/hot air outlet 177 can be configured to permit hot air that passes through the entry portion 155 to pass upward toward the cap 113 of the housing 109. The aperture 177 can be sized and shaped such that all or a portion of the aperture 177 overlaps the connection portion 171 of the hot side heat sink 161 when viewed from above and parallel to the centerline CL of the housing 109. Sizing the aperture 177 in this manner reduces the amount of hot air that passes through the inlet portion 155 and out through the aperture 177 without impacting the connection portion 171 of the hot side heat sink 161.

In the illustrated embodiment, two TEG modules 165 are positioned on opposite sides of the hot side heat sink 161. In some embodiments, three or more TEG modules are used. In some embodiments, only a single TEG module is used. Each TEG module 165 is preferably positioned between the hot side heat sink 161 and a cold side heat sink 141. The TEG module(s) 165 are configured to convert the deltaT between the hot and cold heat sinks into electrical energy. The electrical energy produced by the TEG modules 165 can be directed to the power load 107 and/or to a battery.

As illustrated in FIGS. 11-12, the hot side heat sink 161 can include a first end portion 169a, a second end portion 169b (collectively 169), and a connection portion 171 therebetween. The first and second end portions 169 can have similar or identical shapes to each other. In some embodiments, the cross-sectional shapes and sizes of one or both of the first end portion 169a and second end portion 169b, as measured on a plane parallel to the centerline CL and perpendicular to a length of the connection portion 171, are similar to or the same as the parallel cross-sectional shapes and sizes of the TEG modules 165. Preferably, the cross-sectional areas of the first and second end portions 169 are larger than the parallel cross-sectional areas of the TEG modules 165.

The cross-sectional shape and/or size of the connection portion 171, as measured parallel to the above-described cross-sectional shapes and sizes of the end portions 169, can be different and/or smaller than the cross-sectional shapes and sizes of the end portions 169. For example, as illustrated, the connection portion 171 can have a generally cylindrical shape. In some embodiments, the connection portion 171 has a polygonal, oval, or teardrop cross-section. In some embodiments, the cross-sectional area of the connection portion 171 is less than 90%, less than 75%, less than 60%, and/or less than 50% (but not zero) of the cross-sectional area of each of the end portions 169 or has a cross sectional area that is within a range defined by any two of the aforementioned percentages. Reducing the cross-sectional area of the connection portion 171 reduces the surface area of the connection portion. As explained above, reducing the surface area of the hot side heat sink can greatly reduce the heat loss due to radiation. Reducing heat loss on the hot side heat sink preserves a higher deltaT between the hot and cold sides. Comparing the design of the connection portion 171 to a hot side heat sink that has a constant cross-sectional area (e.g., cube, rectangular prism, or other shape). The connection portion 171 has a reduced surface area, thereby allowing for reduced radiation loss and higher efficiency.

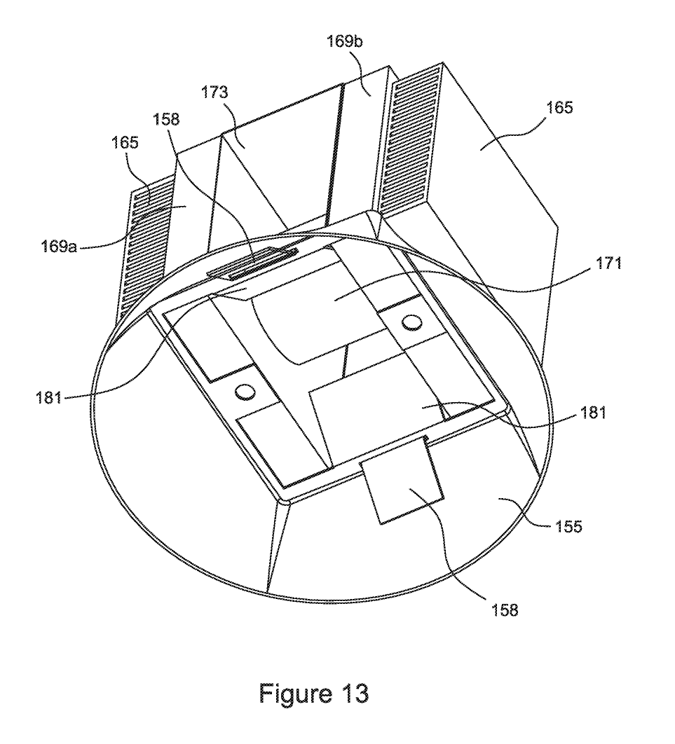

As illustrated in FIG. 13, the entry portion 155 can include one or more airflow directing structures. For example, the entry portion 155 can include one or more angled, curved, and/or stepped walls 181. In the illustrated embodiment, the walls are angled walls 181 angled such that the upper or downstream end of each of the angled walls 181 is closer to the centerline CL of the housing 109 than the lower or upstream end of each of the angled walls 181. In some embodiments, the angled walls 181 are formed as part of the upper portion 157 of the heat shield 153.

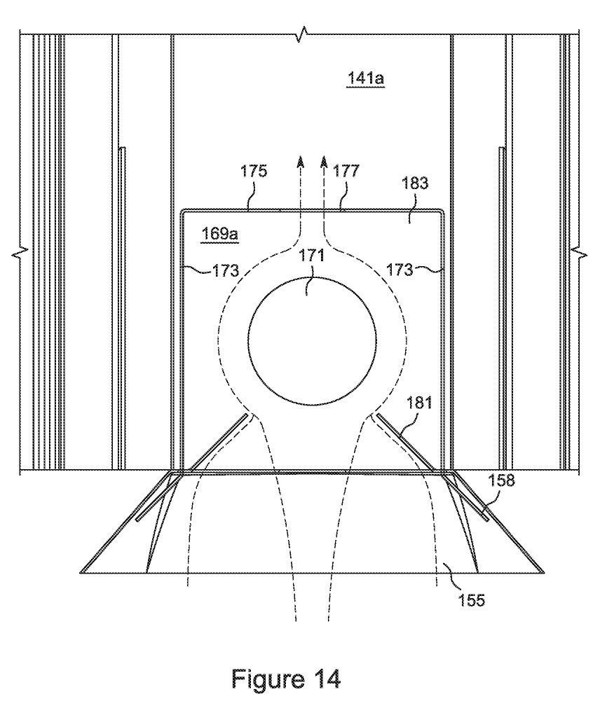

As illustrated in FIG. 14, hot air (represented by the dashed lines) entering the entry portion 155 of the heat shield 153 can be directed toward the connection portion 171 of the hot side heat sink 161 by the angled walls 181. The hot air can then be forced to circulate around the connection portion 171. Circulation of the hot air around the connection portion 171 increases the amount of heat transferred to the connection portion 171 via radiation and convection. The hot air also heats the end portions 169 of the hot side heat sink 161 while travelling from the entry portion 155 to the aperture 177. The relatively small size of the aperture 177 compared to the connection portion 171 can further force the hot air to circulate around the connection portion 171 before exiting through the aperture 177.

In some embodiments, the angled walls 181 contribute to a nozzle effect on the hot air as it passes from the entry portion 155 into the chamber 183 defined by the heat shield 153. When the hot air passes the upper ends of the angled walls 181, a diffusive effect can be imparted on the hot air due to the sudden expansion of the air's flow path. Diffusion of the hot air creates turbulent flow within the chamber 183, thereby increasing the convective heat transfer between the hot air and the hot side heat sink 161.

The size of the aperture 177 can also have a nozzle effect on the hot air—e.g., air passes the connection portion 171 of the hot side heat sink 161 can be accelerated through the aperture 177 due to the small size of the aperture 177 compared to the cross-sectional size of the interior of the chamber 183 below the aperture 177.

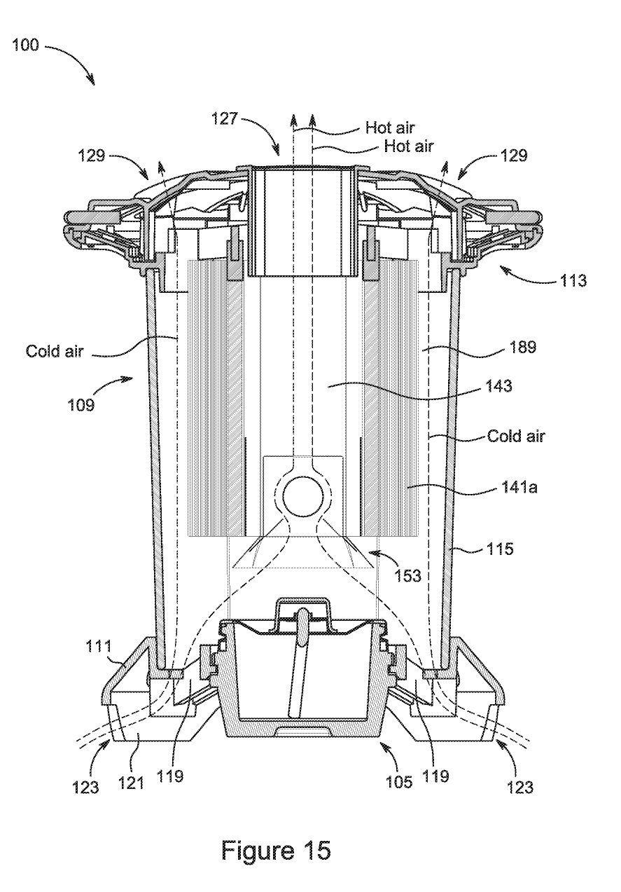

As illustrated in FIG. 15, the configuration of the TEG subassembly 103 and the housing 109 creates two coaxial flow paths through the TEG device 100. The first flow path is through the spaces 123 between the feet 121, through the openings 119 in the lower end of the housing 109/base 111, through the chamber 183 defined by the heat shield and/or hot side heat sink, through the interior passage 143 of the TEG subassembly 103, and through the cap 113 (e.g., through the central opening 127 and/or through secondary air outlets 129). The second flow path is through the spaces 123 between the feet 121, through the openings 119 in the lower end of the housing 109/base 111, through an outer chamber 189 of the housing 109, and through the cap 113 (e.g., through secondary air outlets 129 and/or through the central opening 127). Given that much or all of the air along the first flow path is heated by the heat source 105 and/or accelerated by the heat shield 153, air flow along the first flow path can pull colder air from the secondary flow path and from the outer chamber 189 (e.g., a chamber surrounding the cold side heat sinks) out through the cap 113. In some embodiments, such “pulling” of the colder air is caused by the creation of pressure deficits in the upper portions of the housing 109 due to the velocity of the hot air passing through the interior passage 143 of the TEG subassembly 103 and in the lower portion of the housing 109 due to acceleration of hot air from the heat source 105 and/or from the nozzle effect of the heat shield 153. The pulling of the colder air through the second flow path increases the convective cooling of the cold side heat sinks 141, thereby increasing the power output efficiency of the TEG modules 165. The pulling of cold air in through the openings 119 in the housing 109 also helps to ensure that a sufficient supply of oxygen to the heat source 105 is provided during operation of the TEG device 100.

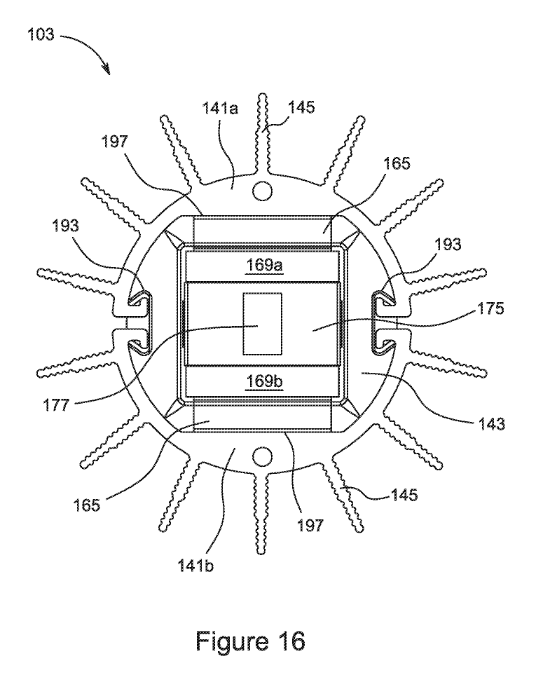

As illustrated in FIG. 16, the first and second cold side heat sinks 141a, 141b can be held together using resilient structures. For example, clips 193 can be used to connect the cold side heat sinks 141a, 141b to each other. In some embodiments, two clips 193 are used. In some embodiments, one clip 193 is used and a hinge is used in place of the second clip. The clips 193 can be constructed from or comprise steel, aluminum, copper, or some other resilient material. The clips 193 impart sufficient force upon the cold side heat sinks 141a, 141b to compress the TEG modules 165 and hot side heat sink 161 therebetween. The resiliency of the clips 193 allows for expansion and contraction (e.g., in response to temperature change) of components of the TEG subassembly 103 without over-compression of those parts by the cold side heat sinks. The cold side heat sinks 141a, 141b can include flattened surfaces 197 in contact with the TEG modules 165 to allow for unidirectional compression of the TEG modules 165 and hot side heat sink 161.

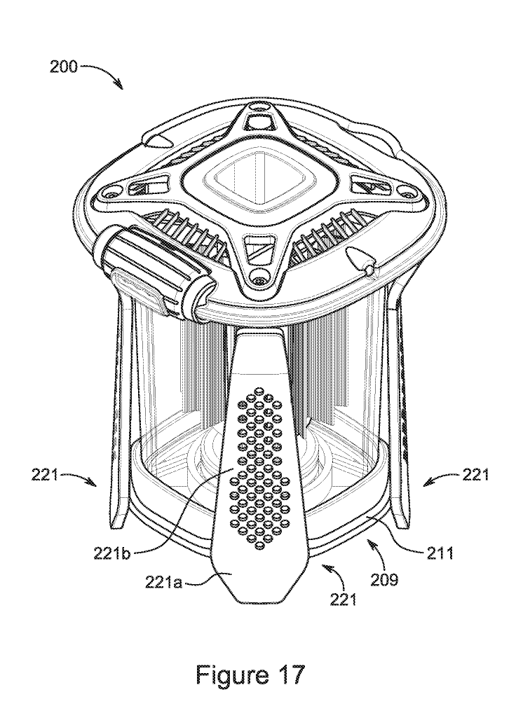

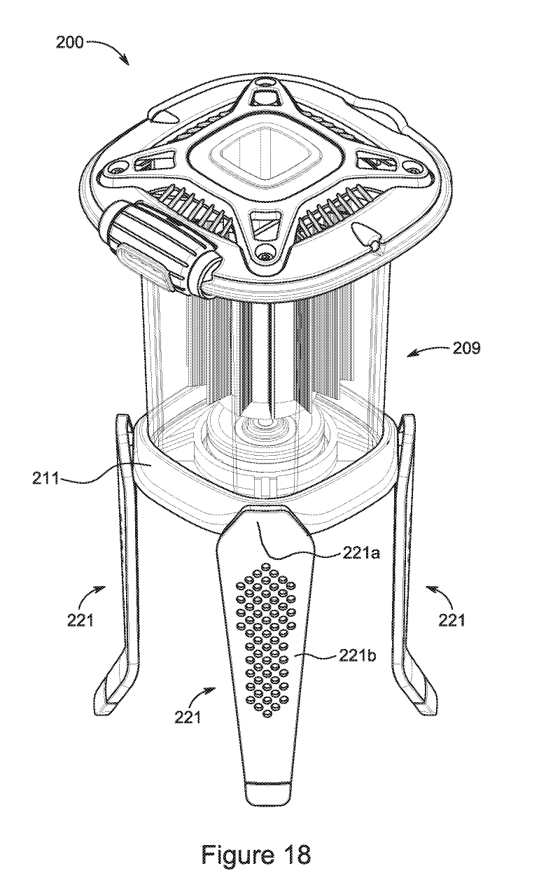

FIGS. 17-18 illustrate an embodiment of a TEG device 200. Unless otherwise noted below, components, structures, and subassemblies of the TEG device 200 can be identical or similar to the corresponding features described above with respect to TEG device 100. For example, the TEG device 200 can include a cap that is similar to or the same as the cap 113 described above.

As illustrated, the TEG device 200 can include a plurality of legs 221. The legs 221 can be configured to space the bottom end of the housing 209 of the TEG device 200 from a surface upon which the TEG device 200 is set. One or more of the legs 221 includes a short side 221a, a long side 221b and a hinge point therebetween. The short side 221a, as illustrated in FIG. 17, can space the bottom end of the housing 209 and/or base 211 a first distance from the surface upon which the TEG device 200 is set. Upon 180° rotation of the legs 221 about their respective hinge points, the long sides 221b of the legs 221 can space the bottom end of the housing 209 and/or base 211 a second distance greater than the first distance from the surface upon which the TEG device 200 is set. In some embodiments, the device 200 is configured to permit partial rotation of the legs 221 in order to realize distances between the first distance and the second distance. For example, the hinges of the legs 221 can be high-friction and/or can include locking mechanisms to allow the user to fix the legs 221 in any desired rotational position (e.g., any position that would not result in interference with another leg).

Accordingly, preferred alternatives relate to:
1. A thermoelectric generator device comprising:
a base including an air inlet;
a housing having a first end connected to the base and a second end opposite the first end;
a cap connected to the second end of the housing and including an air outlet;
a heat source connected to the base;
a thermoelectric module positioned between the heat source and the second end of the housing, the thermoelectric module comprising:
   a hot side heat sink; and
   a cold side heat sink; and
a heat shield assembly comprising:
   an outlet wall extending between the hot side heat sink and the second end of the housing, the outlet wall having an outlet aperture which permits passage of air from the hot side heat sink to the second end of the housing; and
   an inlet wall positioned between the hot side heat sink and the first end of the housing, the inlet wall connected to one or both of the outlet wall and the hot side heat sink, the inlet wall, which directs hot air from the heat source to the hot side heat sink and directs hot air away from the cold side heat sink.
2. The thermoelectric generator device of alternative 1,wherein the cold side heat sink extends at least one half of a distance between the first and second ends of the housing.
3. The thermoelectric generator device of alternative 1 or 2, comprising two cold side heat sinks and two thermoelectric modules, wherein the hot side heat sink is positioned between the two cold side heat sinks and two thermoelectric modules.
4. The thermoelectric generator device of any of alternatives 1-3, wherein the two cold side heat sinks each comprise an inner surface facing away from the housing and an outer surface facing toward the surface, wherein the inner surfaces of the two cold side heat sinks forms an inner air passage and the space between the housing and the outer surfaces of the two heat sinks forms an outer air passage.
5. The thermoelectric generator device of alternative 4, wherein passage of hot air through the outlet aperture of the outlet wall of the heat shield, preferably passes through the inner air passage to the air outlet of the cap, and wherein passage of hot air to the air outlet draws air from the outer air passage to the air outlet.
6. The thermoelectric generator device of any of alternatives 3-5, wherein the two cold side heat sinks are held to each other via one or more resilient clips, and wherein the hot side heat sink is held in place with respect to the two cold heat sinks via compression of the two thermoelectric modules and the hot side heat sink between the two cold side heat sinks.
7. The thermoelectric generator device of alternative 6, wherein the resilient clips deform in response to expansion and contraction of one or more of the thermoelectric modules, the hot side heat sink, and the cold side heat sinks.
8. The thermoelectric generator device of any of alternatives 1-7, wherein the hot side heat sink and cold side heat sink are fixed with respect to each other without use of fasteners.
9. The thermoelectric generator device of any of alternatives 1-8, wherein the base comprises two or more feet, which contact a surface when the thermoelectric generator is set upon the surface, wherein one or more open spaces are created between the two or more feet and the surface when the thermoelectric generator is set upon the surface, and wherein the one or more open spaces, preferably facilitate fluid communication between the air inlet and an ambient environment surrounding the thermoelectric generator device.
10. The thermoelectric generator device of any of alternatives 1-9, wherein the inlet wall of the heat shield has a frustoconical shape having an inlet end with an inlet width and an outlet end with an outlet width, wherein the outlet width is narrower than the inlet width.
11. The thermoelectric generator device of any of alternatives 1-10, further comprising a light source connected to the cap, wherein the thermoelectric module powers the light source.
12. A thermoelectric generator device comprising:
a housing having an inlet wall with an inlet opening, an outlet wall with an outlet opening, an annular wall connected to the inlet and outlet walls and extending therebetween, a housing interior defined by the inlet wall, outlet wall, and the annular wall, and a housing axis extending through a center of the housing interior, through the inlet wall, and through the outlet wall;
a heat source releasably connected to the inlet wall;
a thermoelectric module positioned within the housing interior between the heat source and the second end of the housing, the thermoelectric module comprising:
   a hot side heat sink having a first end portion, a second end portion, and a connection portion extending therebetween;
   a first cold side heat sink positioned on a first side of the hot side heat sink; and
   a second cold side heat sink positioned on a second side of the hot side heat sink; and
a heat shield having a guide wall positioned between the hot side heat sink and the inlet wall of the housing, the guide wall directing hot air from the heat source to the hot side heat sink and directing hot air away from the first and second cold side heat sinks;
wherein the first end portion of the hot side heat sink has a first cross-sectional area as measured on a first plane parallel to the housing axis, the second end portion of the hot side heat sink has a second cross-sectional area as measured on a second plane parallel to the first plane, and the connection portion has a third cross-sectional area as measured on a third plane parallel to the first plane;
wherein the first plane passes through the first end portion and does not pass through the connection portion or the second end portion, the second plane passes through the second end portion and does not pass through the connection portion or the first end portion; and the third plane passes through the connection portion and does not pass through the first or second end portions; and
wherein the third cross-sectional area is less then each of the first and second cross-sectional areas.
13. The thermoelectric generator device of alternative 12, wherein the heat shield comprises walls that surround the connection portion of the hot side heat sink on at least three sides, wherein the walls of the heat shield include an outlet aperture, which permits escape of hot air from within the walls of the heat sink to outlet opening of the outlet wall.
14. The thermoelectric generator device of any of alternatives 12-13, wherein the connection portion of the hot side heat sink has a cylindrical shape and, wherein the third cross-sectional area is a circular cross-section of the connection portion.
15. The thermoelectric generator device of any of alternatives 12-14, wherein the guide wall of the heat shield is connected to one or both of the first and second end portions of the hot side heat sink.
16. The thermoelectric generator device of any of alternatives 12-15, wherein fasteners are used to connect the guide wall to the first and second end portions of the hot side heat sink.
17. The thermoelectric generator device of any of alternatives 12-16, wherein the heat source is connected to the inlet wall of the housing via one or more of a threaded connection, a bayonet connection, and a detent connection.
18. The thermoelectric generator device of any of alternatives 12-17, wherein the heat source is one or more of a candle, an oil holder, or a gas holder.
19. The thermoelectric generator device of any of alternatives 12-18, further comprising two or more legs connected to the housing, wherein the legs are rotatable with respect to the housing between a first orientation and a second orientation, and wherein the legs space the inlet wall of the housing from a surface upon, which the thermoelectric generator device is set when the legs are in the first orientation and space the inlet wall of the housing a further distance from the surface when the legs are in the second orientation.
20. The thermoelectric generator device of any of alternatives 12-19, further comprising a hanger connected to the housing and, which is configured to attach the thermoelectric generator device to a hook or other affixed structure.
21. The thermoelectric generator device of any of alternatives 12-20, further comprising an electric port, which facilitates electric connection between the thermoelectric generator device and an external device, wherein the external device is one or more of a camera, a phone, a GPS device, a laptop, a tablet, a video game console, or a television, and, wherein the thermoelectric module powers the electric port.
22. A method of providing electrical power to an electrical load, the method comprising:
connecting a heat source to an inlet wall of a housing;
directing heated air from the heat source to a hot side heat sink of a thermoelectric module;
blocking at least a portion of the heated air from the heat source from a cold side heat sink of a thermoelectric module;
circulating the heated air within a heat shield surrounding at least three sides of a portion of the hot side heat sink;
directing heated air through an outlet aperture in the heat shield toward an outlet wall of the housing;
pulling cold air through the inlet wall of the housing via a pressure deficit adjacent the inlet wall created by passage of the heated air through the outlet aperture;
cooling a cold side heat sink of the thermoelectric module using the cold air pulled through the inlet wall; and
generating electricity via the thermoelectric module.
23. The method of alternative 22, further comprising powering a light using the generated electricity.
24. The method of alternative 22 or 23, further comprising powering a USB port or other electrical port using the generated electricity.

For expository purposes, the term “horizontal” as used herein is defined as a plane parallel to the plane or surface of the floor of the area in which the system being described is used or the method being described is performed, regardless of its orientation. The term “floor” can be interchanged with the term “ground.” The term “vertical” refers to a direction perpendicular to the horizontal as just defined. Terms such as “above,” “below,” “bottom,” “top,” “side,” “higher,” “lower,” “upper,” “over,” and “under,” are defined with respect to the horizontal plane.

As used herein, the terms “attached,” “connected,” “mated,” and other such relational terms should be construed, unless otherwise noted, to include removable, moveable, fixed, adjustable, and/or releasable connections or attachments. The connections/attachments can include direct connections and/or connections having intermediate structure between the two components discussed.

The terms “approximately,” “about,” “generally,” and “substantially” as used herein represent an amount close to the stated amount that still performs a desired function or achieves a desired result. For example, the terms “approximately,” “about,” “generally,” and “substantially” may refer to an amount that is within less than 10% of the stated amount.

While the preferred embodiments of the present inventions have been described above, it should be understood that they have been presented by way of example only, and not of limitation. It will be apparent to persons skilled in the relevant art that various changes in form and detail can be made therein without departing from the spirit and scope of the inventions. Thus, the present inventions should not be limited by the above-described exemplary embodiments, but should be defined only in accordance with the following claims and their equivalents. Furthermore, while certain advantages of the inventions have been described herein, it is to be understood that not necessarily all such advantages may be achieved in accordance with any particular embodiment of the inventions. Thus, for example, those skilled in the art will recognize that the inventions may be embodied or carried out in a manner that achieves or optimizes one advantage or group of advantages as taught herein without necessarily achieving other advantages as may be taught or suggested herein.

What is claimed is:

1. A thermoelectric generator device comprising:
a base including an air inlet;
a housing having a first end connected to the base and a second end opposite the first end;
a cap connected to the second end of the housing and including an air outlet;
a heat source connected to the base;
a thermoelectric module positioned between the heat source and the second end of the housing, the thermoelectric module comprising:
a hot side heat sink; and
a cold side heat sink; and
a heat shield assembly comprising:
an outlet wall extending between the hot side heat sink and the second end of the housing, the outlet wall having an outlet aperture, which permits passage of air from the hot side heat sink to the second end of the housing; and
an inlet wall positioned between the hot side heat sink and the first end of the housing, the inlet wall connected to one or both of the outlet wall and the hot side heat sink, the inlet wall, which directs hot air from the heat source to the hot side heat sink and directs hot air away from the cold side heat sink.

2. The thermoelectric generator device of claim 1, wherein the cold side heat sink extends at least one half of a distance between the first and second ends of the housing.

3. The thermoelectric generator device of claim 1, comprising two cold side heat sinks and two thermoelectric modules, wherein the hot side heat sink is positioned between the two cold side heat sinks and two thermoelectric modules.

4. The thermoelectric generator device of claim 3, wherein the two cold side heat sinks each comprise an inner surface facing away from the housing and an outer surface facing toward the surface, wherein the inner surfaces of the two cold side heat sinks forms an inner air passage and the space between the housing and the outer surfaces of the two heat sinks forms an outer air passage.

5. The thermoelectric generator device of claim 4, wherein passage of hot air through the outlet aperture of the outlet wall of the heat shield passes through the inner air passage to the air outlet of the cap, and wherein passage of hot air to the air outlet draws air from the outer air passage to the air outlet.

6. The thermoelectric generator device of claim 3, wherein the two cold side heat sinks are held to each other via one or more resilient clips, and wherein the hot side heat sink is held in place with respect to the two cold heat sinks via compression of the two thermoelectric modules and the hot side heat sink between the two cold side heat sinks.

7. The thermoelectric generator device of claim 6, wherein the resilient clips deform in response to expansion and contraction of one or more of the thermoelectric modules, the hot side heat sink, and the cold side heat sinks.

8. The thermoelectric generator device of claim 1, wherein the hot side heat sink and cold side heat sink are fixed with respect to each other without use of fasteners.

9. The thermoelectric generator device of claim 1, wherein the base comprises two or more feet, which contact a surface when the thermoelectric generator is set upon the surface, wherein one or more open spaces are created between the two or more feet and the surface when the thermoelectric generator is set upon the surface, and wherein the one or more open spaces facilitate fluid communication between the air inlet and an ambient environment surrounding the thermoelectric generator device.

10. The thermoelectric generator device of claim 1, wherein the inlet wall of the heat shield has a frustoconical shape having an inlet end with an inlet width and an outlet end with an outlet width, wherein the outlet width is narrower than the inlet width.

11. The thermoelectric generator device of claim 1, further comprising a light source connected to the cap, wherein the thermoelectric module powers the light source.

12. A thermoelectric generator device comprising:
a housing having an inlet wall with an inlet opening, an outlet wall with an outlet opening, an annular wall connected to the inlet and outlet walls and extending therebetween, a housing interior defined by the inlet wall, outlet wall, and the annular wall, and a housing axis extending through a center of the housing interior, through the inlet wall, and through the outlet wall;
a heat source releasably connected to the inlet wall;
a thermoelectric module positioned within the housing interior between the heat source and the second end of the housing, the thermoelectric module comprising:
a hot side heat sink having a first end portion, a second end portion, and a connection portion extending therebetween;
a first cold side heat sink positioned on a first side of the hot side heat sink; and
a second cold side heat sink positioned on a second side of the hot side heat sink; and
a heat shield having a guide wall positioned between the hot side heat sink and the inlet wall of the housing, the guide wall directs hot air from the heat source to the hot side heat sink and to direct hot air away from the first and second cold side heat sinks;
wherein the first end portion of the hot side heat sink has a first cross-sectional area as measured on a first plane parallel to the housing axis, the second end portion of the hot side heat sink has a second cross-sectional area as measured on a second plane parallel to the first plane, and the connection portion has a third cross-sectional area as measured on a third plane parallel to the first plane;
wherein the first plane passes through the first end portion and does not pass through the connection portion or the second end portion, the second plane passes through the second end portion and does not pass through the connection portion or the first end portion; and the third plane passes through the connection portion and does not pass through the first or second end portions; and
wherein the third cross-sectional area is less then each of the first and second cross-sectional areas.

13. The thermoelectric generator device of claim 12, wherein the heat shield comprises walls that surround the connection portion of the hot side heat sink on at least three sides, wherein the walls of the heat shield include an outlet aperture, which permits escape of hot air from within the walls of the heat sink to outlet opening of the outlet wall.

14. The thermoelectric generator device of claim 12, wherein the connection portion of the hot side heat sink has a cylindrical shape and wherein the third cross-sectional area is a circular cross-section of the connection portion.

15. The thermoelectric generator device of claim 12, wherein the guide wall of the heat shield is connected to one or both of the first and second end portions of the hot side heat sink.

16. The thermoelectric generator device of claim 15, wherein fasteners are used to connect the guide wall to the first and second end portions of the hot side heat sink.

17. The thermoelectric generator device of claim 12, wherein the heat source is connected to the inlet wall of the housing via one or more of a threaded connection, a bayonet connection, and a detent connection.

18. The thermoelectric generator device of claim 12, wherein the heat source is one or more of a candle, an oil holder, or a gas holder.

19. The thermoelectric generator device of claim 12, further comprising two or more legs connected to the housing, wherein the legs are rotatable with respect to the housing between a first orientation and a second orientation, and wherein the legs space the inlet wall of the housing from a surface upon, which the thermoelectric generator device is set when the legs are in the first orientation and space the inlet wall of the housing a further distance from the surface when the legs are in the second orientation.

20. The thermoelectric generator device of claim 12, further comprising a hanger connected to the housing and, which is configured to attach the thermoelectric generator device to a hook or other affixed structure.

21. The thermoelectric generator device of claim 12, further comprising an electric port, which facilitates electric connection between the thermoelectric generator device and an external device, wherein the external device is one or more of a camera, a phone, a GPS device, a laptop, a tablet, a video game console, or a television, and, wherein the thermoelectric module powers the electric port.

22. A method of providing electrical power to an electrical load, the method comprising:
connecting a heat source to an inlet wall of a housing;
directing heated air from the heat source to a hot side heat sink of a thermoelectric module;
blocking at least a portion of the heated air from the heat source from a cold side heat sink of a thermoelectric module;
circulating the heated air within a heat shield surrounding at least three sides of a portion of the hot side heat sink;
directing heated air through an outlet aperture in the heat shield toward an outlet wall of the housing;
pulling cold air through the inlet wall of the housing via a pressure deficit adjacent the inlet wall created by passage of the heated air through the outlet aperture;
cooling a cold side heat sink of the thermoelectric module using the cold air pulled through the inlet wall; and
generating electricity via the thermoelectric module.

23. The method of claim 22, further comprising powering a light using the generated electricity.

24. The method of claim 22, further comprising powering a USB port or other electrical port using the generated electricity.
